(19) United States
(12) Patent Application Publication
(10) Pub. No.: US 2025/0391749 A1
(43) Pub. Date: Dec. 25, 2025

(54) ELECTRONIC COMPONENT BRACKET, MANUFACTURING PROCESS THEREOF, AND ENCAPSULATED PRODUCT

(71) Applicant: Fujian Lightning Optoelectronic Co., Ltd., Fujian (CN)

(72) Inventors: Hungyang Lin, Fujian (CN); Yu Chen, Fujian (CN); Tan He, Fujian (CN); Shenche Lee, Fujian (CN); Xihong Wan, Fujian (CN); Yuhou Lei, Fujian (CN)

(21) Appl. No.: 19/231,356

(22) Filed: Jun. 6, 2025

(30) Foreign Application Priority Data
Jun. 19, 2024 (CN) 202410788383.7

(51) Int. Cl. H01L 23/495; H01L 21/48; H01S 5/0232; H10H 20/01; H10H 20/857

(52) U.S. Cl. CPC H01L 23/49558; H01L 21/4828; H01L 21/4842; H01L 23/49534; H01S 5/0232; H10H 20/0364; H10H 20/857

(57) ABSTRACT

Provided are an electronic component bracket, a manufacturing process therefor, and an encapsulated product. The electronic component bracket includes a metal sheet assembly, an internally filled resin layer, a bottom resin layer, and a top resin layer. The metal sheet assembly includes a positive metal sheet and a negative metal sheet, and connecting rib sections are disposed on a side surface of each of the positive metal sheet and the negative metal sheet. The top resin layer includes a tubular structure and protrusions that are integrally connected, and the protrusions are arranged at an outer edge of a bottom surface of the tubular structure. The protrusions cover the connecting rib sections. A top surface of the bottom resin layer is provided with accommodation grooves in fit with the protrusions.

### CROSS-REFERENCE TO RELATED APPLICATION(S)

This patent application claims the benefit and priority of Chinese Patent Application No. 202410788383.7 filed with the China National Intellectual Property Administration on Jun. 19, 2024, the disclosure of which is incorporated by reference herein in its entirety as part of the present application.

### TECHNICAL FIELD

The present disclosure relates to the technical field of electronic elements, and in particular to an electronic component bracket, a manufacturing process therefor, and an encapsulated product.

### BACKGROUND

A structure of an encapsulated product before encapsulation may be called an electronic component bracket, which includes a positive metal sheet, a negative metal sheet and resin. In the prior art, a manufacturing process of the electronic component bracket generally includes the following steps.
S1. A copper sheet is etched and electroplated to obtain a lead frame, where the lead frame includes multiple array units arranged in an array, and each array unit includes a positive metal sheet and a negative metal sheet having a same thickness, a space between the positive metal sheet and the negative metal sheet in a same array unit is completely hollowed out, the positive metal sheet and the positive metal sheet, the positive metal sheet and the negative metal sheet as well as the negative metal sheet and the negative metal sheet of the two adjacent array units are respectively connected by connecting ribs, and a thickness of the connecting rib is less than that of each of the positive metal sheet and the negative metal sheet.
S2. The resin is molded on the lead frame, so that the resin not only completely fills hollow-out portions and grooves on the lead frame but also form a grid structure on a top surface of the lead frame, and ribs of the grid cover the connecting ribs.
S3. The connecting ribs and middle portions of the ribs are simultaneously cut off along the ribs of the grid to obtain multiple electronic component brackets.

For the electronic component bracket fabricated by the above process, an end of the connecting rib can be seen on a section plane, that is, a gap between the connecting rib and the resin is exposed. A light-sensitive or harmful substance is prone to invading through the gap between the lead frame and the resin, which leads to discoloration of a plating of the lead frame or deterioration and attenuation of an encapsulation material.

### SUMMARY

An objective of the present disclosure is to provide an electronic component bracket, a manufacturing process thereof, and an encapsulated product, thereby solving the problems in the prior art and improving reliability of a product.

To achieve the objective above, the present disclosure provides the following technical solution.

The present disclosure provides an electronic component bracket, including a metal sheet assembly, an internally filled resin layer, a bottom resin layer, and a top resin layer, where the internally filled resin layer is integrally connected to the bottom resin layer;
the metal sheet assembly includes at least a positive metal sheet and a negative metal sheet; connecting rib sections formed by removing connecting ribs are disposed on a side surface of the positive metal sheet and a side surface of the negative metal sheet, and the internally filled resin layer fills a gap between the positive metal sheet and the negative metal sheet;
an integral structure composed of the metal sheet assembly and the internally filled resin layer is an integrated unit;
the top resin layer includes a tubular structure and protrusions that are integrally connected, and the protrusions are arranged at an outer edge of a bottom surface of the tubular structure, the tubular structure covers an outer edge of a top surface of the integrated unit, and the protrusions cover the connecting rib sections;
the bottom resin layer is annular and sleeved outside the integrated unit, and a top surface of the bottom resin layer is provided with accommodation grooves in fit with the protrusions;
for a side surface of the integrated unit, a portion other than the connecting rib sections is covered with an inner side surface of the bottom resin layer, and the top surface of the bottom resin layer is covered with the top resin layer.

In some embodiments, an inner hole of the tubular structure is tapered, and an end with a smallest cross-sectional area of the inner hole of the tubular structure is connected to the top surface of the integrated unit.

In some embodiments, the electronic component bracket further includes an inner covering resin layer that covers a top surface of the internally filled resin layer.

In some embodiments, the top resin layer partially covers a top surface of the positive metal sheet and a top surface of the negative metal sheet.

The present disclosure further provides a manufacturing process of an electronic component bracket. The manufacturing process is used for preparing the electronic component bracket described above, and includes the following steps:
S1: etching a metal sheet to obtain a lead frame, where the lead frame includes multiple array units arranged in an array, each of the multiple array units includes at least the positive metal sheet and the negative metal sheet, in each of the multiple array units, a space between the positive metal sheet and the negative metal sheet corresponding to a same electrical device is completely hollowed out, two adjacent array units of the multiple array units are connected by a corresponding one of the connecting ribs, a thickness of each of the connecting ribs is less than that of each of the multiple array units, and two ends of each of the connecting ribs are connected to bottoms of side surfaces of corresponding ones of the multiple array units;
S2: molding resin on the lead frame, and filling hollow-out portions and grooves on the lead frame with the resin to obtain a flat integrated board;
S3: removing all or middle portions of the connecting ribs to disconnect the two adjacent array units, connecting the two adjacent array units merely by the resin filled in S2; after removing the connecting ribs, forming the accommodation grooves at a top surface of the flat integrated board, where the connecting rib sections are arranged in the accommodation grooves;
S4: molding resin on a structure obtained in S3, where the molded resin not only fills the accommodation grooves, but also forms a grid on a top surface of the structure obtained in S3; and
S5: cutting off middle portions of ribs of the grid along the ribs of the grid to obtain multiple independent electronic component brackets.

In some embodiments, in S3, a way to remove the connecting ribs is cutting or etching.

In some embodiments, between S1 and S2, the manufacturing process further includes a procedure of electroplating the lead frame.

In some embodiments, after S5, the manufacturing process further includes a procedure of electroplating the positive metal sheet and the negative metal sheet.

The present disclosure further provides an encapsulated product, including the electronic component bracket described above, and further including a chip and an encapsulation layer, where the chip is electrically connected to the positive metal sheet and the negative metal sheet, the encapsulation layer is configured to encapsulate the chip, and the chip and the encapsulation layer are both located on an inner side of the tubular structure.

In some embodiments, the chip is any one of an LED chip, a laser chip, and an IC chip.

Compared with the prior art, embodiments of the present disclosure achieve the following technical effects.

According to embodiments of the present disclosure, an accommodation groove formed by removing the connecting rib is filled with a protrusion structure on a bottom surface of a top resin layer, and the protrusion structure covers a connecting rib section, thereby achieving an effect of not exposing the connecting rib section. Therefore, the side surface of the metal sheet assembly can be completely covered to prevent a light-sensitive or harmful substance from invading through a gap between the connecting rib and the resin, thereby improving reliability of the electronic component bracket.

### BRIEF DESCRIPTION OF THE DRAWINGS

To describe the technical solutions of the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a side surface structure of an electronic component bracket obtained by an existing technology;

FIG. 2 is a schematic diagram in a top view direction of an encapsulated product according to an embodiment of the present disclosure;

FIG. 3 is a schematic diagram in a side view direction of an encapsulated product according to an embodiment of the present disclosure;

FIG. 4 is a front view of a lead frame; and

FIG. 5 is a side view of a lead frame.

In the drawings: 1 connecting rib section; 2 positive metal sheet; 3 negative metal sheet; 4 internally filled resin layer; 5 bottom resin layer; 6 inner covering resin layer; 7 top resin layer; 8 metal plating; 9 chip; 10 encapsulation layer; 11 bonding wire; 12 lead frame; 13 array unit; 14 connecting rib.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the scope of protection of the present disclosure.

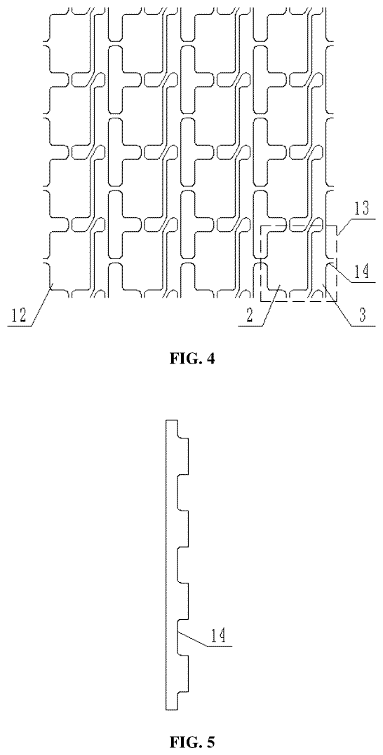

Referring to FIG. 2 and FIG. 3, the embodiment provides an electronic component bracket, including a metal sheet assembly, an internally filled resin layer 4, a bottom resin layer 5, and a top resin layer 7. The internally filled resin layer 4 is integrally connected to the bottom resin layer 5.

The metal sheet assembly includes at least a positive metal sheet 2 and a negative metal sheet 3. Connecting rib sections 1 formed by removing connecting ribs 14 are disposed on a side surface of the positive metal sheet 2 and a side surface of the negative metal sheet 3, and the internally filled resin layer 4 fills a gap between the positive metal sheet 2 and the negative metal sheet 3.

An integral structure composed of the metal sheet assembly and the internally filled resin layer 4 is an integrated unit.

The top resin layer 7 includes a tubular structure and protrusions that are integrally connected, and the protrusions are arranged at an outer edge of a bottom surface of the tubular structure. The tubular structure covers an outer edge of a top surface of the integrated unit, and the protrusions cover the connecting rib sections 1.

The bottom resin layer 5 is annular and sleeved outside the integrated unit, and a top surface of the bottom resin layer 5 is provided with accommodation grooves in fit with the protrusions.

For a side surface of the integrated unit, a portion other than the connecting rib sections 1 is covered with an inner side surface of the bottom resin layer 5, and the top surface of the bottom resin layer 5 is covered with the top resin layer 7.

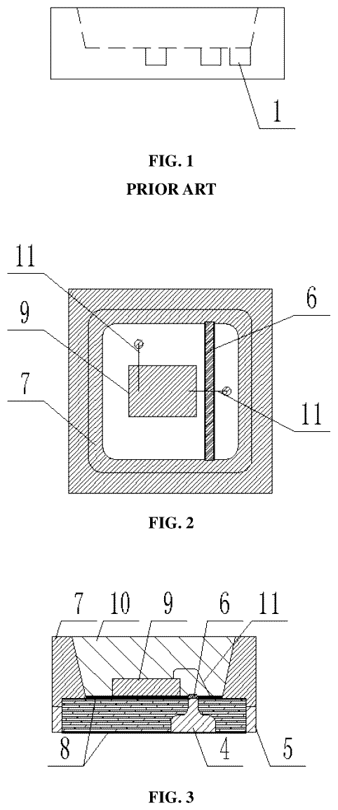

A working principle of the electronic component bracket in this embodiment is as follows:
according to the electronic component bracket in the prior art, referring to FIG. 1, the connecting rib sections 1 are exposed on a side surface of the electronic component bracket and in direct contact with the outside air. With aging of the resin and corrosion of the metal on a surface of the connecting rib, a joint between the connecting rib 14 and the resin is prone to expand, and external impurities are easy to invade through this joint.

In the embodiment, an accommodation groove formed by removing the connecting rib 14 is filled with a protrusion structure on a bottom surface of the top resin layer 7, and the protrusion structure covers the connecting rib section 1, thereby achieving an effect of not exposing the connecting rib section 1, that is, a single electronic component bracket has no exposed pins. Therefore, in this embodiment, the side surface of the metal sheet assembly can be completely covered to prevent a light-sensitive or harmful substance from invading through the gap between the connecting rib 14 and the resin, thereby improving reliability of the electronic component bracket.

As a possible example, in this embodiment, the top resin layer 7 partially covers a top surface of the positive metal sheet 2 and a top surface of the negative metal sheet 3, with an installation region of the chip 9 left.

As a possible example, in this embodiment, an inner hole of the tubular structure is tapered, and an end with a smallest cross-sectional area of the inner hole of the tubular structure is connected to the top surface of the integrated unit. A surface of the conical inner hole can reflect light, so that after a light-emitting element is installed on an inner side of the tubular structure, more light rays can be emitted to a side away from the metal sheet assembly, thereby improving the brightness.

To make the bottom resin layer 5 and the top resin layer 7 have better bonding, it is preferable that the bottom resin layer 5 and the top resin layer 7 are made of a same material.

As a possible example, in this embodiment, the electronic component bracket further includes an inner covering resin layer 6 that covers a top surface of the internally filled resin layer 4. The material of the inner covering resin layer 6 and the material of the top resin layer 7 can be the same or different.

As a possible example, in this embodiment, the metal sheet assembly is made of copper. According to actual needs, those skilled in the art may also choose other types of conductive metals, such as iron or other alloys (copper alloy, iron alloy).

The embodiment further provides a manufacturing process of an electronic component bracket, which is used for preparing the electronic component bracket described above, and includes the following steps.
S1. Referring to FIG. 4 and FIG. 5, a lead frame 12 is obtained after etching a metal sheet, the lead frame 12 includes multiple array units 13 arranged in an array, and each array unit 13 includes at least a positive metal sheet 2 and a negative metal sheet 3. In one array unit 13, a space between the positive metal sheet 2 and the negative metal sheet 3 corresponding to a same electrical device (such as a chip 9 in the following) is completely hollowed out (for avoiding short-circuiting), and two adjacent array units 13 are connected by a connecting rib 14. A thickness of the connecting rib 14 is less than that of the array unit 13, and both ends of the connecting rib 14 are connected to the bottoms of side surfaces of the array units 13.
S2. Resin is molded on the lead frame 12 to make the resin fill hollow-out portions and grooves on the lead frame 12 to obtain a flat integrated board.
S3. All or middle portions of the connecting ribs 14 is removed to disconnect the two adjacent array units 13. In this case, the two adjacent array units 13 are connected merely by the resin filled in S2. After removing the connecting ribs 14, accommodation grooves are formed at a top surface of the flat integrated board, and the connecting rib sections 1 are arranged in the accommodation grooves.
S4. Resin is molded on a structure obtained in S3, the molded resin not only fills the accommodation grooves, but also forms a grid on a top surface of the structure obtained in S3.
S5. Middle portions of ribs are cut off along the ribs of the grid to obtain multiple independent electronic component brackets, all of which have no exposed pins.

As a possible example, in this embodiment, in S3, a way to remove the connecting ribs 14 is cutting or etching.

As a possible example, in this embodiment, between S1 and S2, the manufacturing process further includes a procedure of electroplating the lead frame 12.

As a possible example, in this embodiment, after S5, the manufacturing process further includes a procedure of electroplating the positive metal sheet 2 and the negative metal sheet 3.

Referring to FIG. 2 and FIG. 3, this embodiment further provides an encapsulated product, including the electronic component bracket described above, and further including a chip 9, and an encapsulation layer 10. The chip 9 is electrically connected to the positive metal sheet 2 and the negative metal sheet 3, and the encapsulation layer 10 is configured to encapsulate the chip 9. The chip 9 and the encapsulation layer 10 are both located on an inner side of the tubular structure.

There are many electrical connection modes of the chip 9, and those skilled in the art can choose the electrical connection mode according to actual needs. When the chip 9 is a horizontal traditional package structure or a vertical structure, the chip 9 is electrically connected to the positive metal sheet 2 and the negative metal sheet 3 in a manner of welding a bonding wire 11. When the chip 9 is a flip-chip structure, there is no need to weld the bonding wire 11, a positive electrode of the chip 9 is directly connected to the positive metal sheet 2, and a negative electrode of the chip 9 is directly connected to the negative metal sheet 3.

As the encapsulated product includes the electronic component bracket described above, the encapsulated product also has the advantages of the electronic component bracket described above, which will not be described in detail here.

According to actual needs, those skilled in the art may also choose the type of the chip 9 flexibly. As a possible example, in this embodiment, the chip 9 is any one of an LED (light-emitting diode) chip, a laser chip, an IC (integrated circuit) chip and a flip chip.

As a possible example, in this embodiment, the encapsulation layer 10 is made of any one of silicone, epoxy resin, silicon dioxide, and glass. According to actual needs, other materials can be mixed and added into the encapsulation layer 10. For example, the encapsulation layer 10 is also mixed with a light conversion material, a light diffusion material or a light reflection material. The mixed material may specifically be at least one of fluorescent powder, silica particles, and titanium dioxide particles.

Specific examples are used herein for illustration of the principles and embodiments of the present disclosure. The description of the embodiments is merely used to help illustrate the method and its core principles of the present disclosure. In addition, those of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. An electronic component bracket, comprising:
a metal sheet assembly;
an internally filled resin layer;
a bottom resin layer; and
a top resin layer,
wherein:
the internally filled resin layer is integrally connected to the bottom resin layer;
the metal sheet assembly comprises at least a positive metal sheet and a negative metal sheet, connecting rib sections formed by removing connecting ribs are disposed on a side surface of the positive metal sheet and a side surface of the negative metal sheet, and the internally filled resin layer fills a gap between the positive metal sheet and the negative metal sheet;
an integral structure composed of the metal sheet assembly and the internally filled resin layer is an integrated unit;
the top resin layer comprises a tubular structure and protrusions that are integrally connected, and the protrusions are arranged at an outer edge of a bottom surface of the tubular structure, the tubular structure covers an outer edge of a top surface of the integrated unit, and the protrusions cover the connecting rib sections;
the bottom resin layer is annular and sleeved outside the integrated unit, and a top surface of the bottom resin layer is provided with accommodation grooves in fit with the protrusions; and
for a side surface of the integrated unit, a portion other than the connecting rib sections is covered with an inner side surface of the bottom resin layer, and the top surface of the bottom resin layer is covered with the top resin layer.

2. The electronic component bracket according to claim 1, wherein an inner hole of the tubular structure is tapered, and an end with a smallest cross-sectional area of the inner hole of the tubular structure is connected to the top surface of the integrated unit.

3. The electronic component bracket according to claim 1, further comprising an inner covering resin layer that covers a top surface of the internally filled resin layer.

4. The electronic component bracket according to claim 1, wherein the top resin layer partially covers a top surface of the positive metal sheet and a top surface of the negative metal sheet.

5. A manufacturing process of manufacturing the electronic component bracket according to claim 1, the manufacturing process comprising the following steps:
S1: etching a metal sheet to obtain a lead frame, wherein the lead frame comprises a plurality of array units arranged in an array, each of the plurality of array units comprises at least the positive metal sheet and the negative metal sheet, in each of the plurality of array units, a space between the positive metal sheet and the negative metal sheet corresponding to a same electrical device is completely hollowed out, two adjacent array units of the plurality of array units are connected by a corresponding one of the connecting ribs, a thickness of each of the connecting ribs is less than that of each of the plurality of array units, and two ends of each of the connecting ribs are connected to bottoms of side surfaces of corresponding ones of the plurality of array units;
S2: molding resin on the lead frame, and filling hollow-out portions and grooves on the lead frame with the resin to obtain a flat integrated board;
S3: removing all or middle portions of the connecting ribs to disconnect the two adjacent array units, connecting the two adjacent array units merely by the resin filled in step S2; and after removing the connecting ribs, forming the accommodation grooves at a top surface of the flat integrated board, wherein the connecting rib sections are arranged in the accommodation grooves;
S4: molding resin on a structure obtained by step S3, wherein the molded resin not only fills the accommodation grooves, but also forms a grid on a top surface of the structure obtained by step S3; and
S5: cutting off middle portions of ribs of the grid along the ribs of the grid to obtain a plurality of independent electronic component brackets.

6. The manufacturing process according to claim 5, wherein in step S3, the connecting ribs are removed by cutting or etching.

7. The manufacturing process according to claim 5, wherein between steps S1 and S2, the manufacturing process further comprises a procedure of electroplating the lead frame.

8. The manufacturing process according to claim 5, wherein after step S5, the manufacturing process further comprises a procedure of electroplating the positive metal sheet and the negative metal sheet.

9. The manufacturing process according to claim 5, wherein an inner hole of the tubular structure is tapered, and an end with a smallest cross-sectional area of the inner hole of the tubular structure is connected to the top surface of the integrated unit.

10. The manufacturing process according to claim 9, wherein in step S3, the connecting ribs are removed by cutting or etching.

11. The manufacturing process according to claim 5, wherein the electronic component bracket further comprises an inner covering resin layer that covers a top surface of the internally filled resin layer.

12. The manufacturing process according to claim 5, wherein the top resin layer partially covers a top surface of the positive metal sheet and a top surface of the negative metal sheet.

13. An encapsulated product, comprising:
the electronic component bracket according to claim 1;
a chip; and
an encapsulation layer,
wherein the chip is electrically connected to the positive metal sheet and the negative metal sheet, the encapsulation layer is configured to encapsulate the chip, and the chip and the encapsulation layer are both located on an inner side of the tubular structure.

14. The encapsulated product according to claim 13, wherein the chip is any one selected from the group consisting of an LED chip, a laser chip, and an IC chip.

15. The encapsulated product according to claim 13, wherein an inner hole of the tubular structure is tapered, and an end with a smallest cross-sectional area of the inner hole of the tubular structure is connected to the top surface of the integrated unit.

16. The encapsulated product according to claim 15, wherein the chip is any one selected from the group consisting of an LED chip, a laser chip, and an IC chip.

17. The encapsulated product according to claim 13, wherein the electronic component bracket further comprises an inner covering resin layer that covers a top surface of the internally filled resin layer.

18. The encapsulated product according to claim 17, wherein the chip is any one selected from the group consisting of an LED chip, a laser chip, and an IC chip.

19. The encapsulated product according to claim 13, wherein the top resin layer partially covers a top surface of the positive metal sheet and a top surface of the negative metal sheet.

20. The encapsulated product according to claim 19, wherein the chip is any one selected from the group consisting of an LED chip, a laser chip, and an IC chip.
